(19) United States
(12) Patent Application Publication
(10) Pub. No.: US 2024/0264429 A1
(43) Pub. Date: Aug. 8, 2024

(54) MIRROR DEVICE

(71) Applicant: HAMAMATSU PHOTONICS K.K., Hamamatsu-shi (JP)

(72) Inventors: Tomoyuki IDE, Hamamatsu-shi (JP); Daiki SUZUKI, Hamamatsu-shi (JP)

(73) Assignee: HAMAMATSU PHOTONICS K.K., Hamamatsu-shi (JP)

(21) Appl. No.: 18/432,346

(22) Filed: Feb. 5, 2024

(30) Foreign Application Priority Data
Feb. 7, 2023 (JP) 2023-016821

(51) Int. Cl. G02B 26/08

(52) U.S. Cl. CPC G02B 26/0825

(57) ABSTRACT

In a mirror device, a first rib portion includes a pair of first portions extending toward one side in a first direction and a first extending portion extending between the first portions. A second rib portion includes a pair of second portions extending toward the other side in the first direction and a second extending portion extending between the second portions. A third rib portion includes a pair of third portions extending toward one side in a second direction. A fourth rib portion includes a pair of fourth portions extending toward the other side in the second direction. A rib portion does not include portions formed between the third portions and between the fourth portions and extending to intersect the second axis when viewed in a third direction. The first to fourth portions are portions different from one another.

### TECHNICAL FIELD

One aspect of the present disclosure relates to a mirror device.

### BACKGROUND

For example, Japanese Unexamined Patent Publication No. 2004-325578 describes a deflection mirror in which a movable portion having a mirror surface is swingably coupled to a support portion. In the deflection mirror described in Patent Literature 1, in order to reduce distortion of the mirror surface during driving, a rib is formed on a back surface of the movable portion.

In the mirror device described above, effectively suppressing distortion of the mirror surface, and being able to satisfactorily swing the movable portion or ensuring reliability are required.

### SUMMARY

Therefore, an object of one aspect of the present disclosure is to provide a mirror device capable of effectively suppressing distortion of a mirror surface and ensuring reliability while realizing good swinging of a movable portion.

[1] According to one aspect of the present disclosure, there is provided a mirror device including: “a support portion; a movable portion having a first surface and a second surface opposite to the first surface, a mirror surface being formed on the first surface and a rib portion being formed on the second surface; and a coupling portion that couples the movable portion to the support portion such that the movable portion is swingable around a first axis. The rib portion includes a first rib portion, a second rib portion, a third rib portion, and a fourth rib portion. When a direction parallel to the first axis is a first direction, an axis perpendicular to both the first direction and a third direction passing through a center of the movable portion when viewed in the third direction perpendicular to the second surface is a second axis, and a direction parallel to the second axis is a second direction, the first rib portion includes a pair of first portions extending from a side of a reference position toward one side in the first direction and facing each other with the first axis interposed between the pair of first portions in the second direction, and a first extending portion extending between the pair of first portions to intersect the first axis when viewed in the third direction, the second rib portion includes a pair of second portions extending from the side of the reference position toward the other side in the first direction and facing each other with the first axis interposed between the pair of second portions in the second direction, and a second extending portion extending between the pair of second portions to intersect the first axis when viewed in the third direction, the third rib portion includes a pair of third portions extending from the side of the reference position toward one side in the second direction and facing each other with the second axis interposed between the pair of third portions in the first direction, and the fourth rib portion includes a pair of fourth portions extending from the side of the reference position toward the other side in the second direction and facing each other with the second axis interposed between the pair of fourth portions in the first direction. The rib portion does not include a portion formed between the pair of third portions and extending to intersect the second axis when viewed in the third direction, and a portion formed between the pair of fourth portions and extending to intersect the second axis when viewed in the third direction. The pair of first portions, the pair of second portions, the pair of third portions, and the pair of fourth portions are portions different from one another.”

In the mirror device, the rib portion includes the first rib portion, the second rib portion, the third rib portion, and the fourth rib portion. The first rib portion includes the pair of first portions extending from the side of the reference position toward the one side in the first direction and facing each other with the first axis interposed between the pair of first portions in the second direction, and the first extending portion extending between the pair of first portions to intersect the first axis when viewed in the third direction, the second rib portion includes the pair of second portions extending from the side of the reference position toward the other side in the first direction and facing each other with the first axis interposed between the pair of second portions in the second direction, and the second extending portion extending between the pair of second portions to intersect the first axis when viewed in the third direction, the third rib portion includes the pair of third portions extending from the side of the reference position toward the one side in the second direction and facing each other with the second axis interposed between the pair of third portions in the first direction, and the fourth rib portion includes the pair of fourth portions extending from the side of the reference position toward the other side in the second direction and facing each other with the second axis interposed between the pair of fourth portions in the first direction. Accordingly, the rib portion can be disposed on the movable portion in a well-balanced manner, and distortion of the movable portion (in other words, distortion of the mirror surface) can be effectively suppressed. On the other hand, when the movable portion swings, stress generated in the coupling portion may be transmitted to the rib portion, and from the viewpoint of preventing the rib portion from being damaged or peeled off due to the stress, reinforcing the rib portion can be considered. However, for example, when the rib portion is reinforced simply by connecting rib portions, the moment of inertia of the movable portion around the first axis may increase depending on the connection location. In this regard, in the mirror device, the first rib portion includes the first extending portion extending between the pair of first portions to intersect the first axis when viewed in the third direction, and the second rib portion includes the second extending portion extending between the pair of second portions to intersect the first axis when viewed in the third direction, whereas the rib portion does not include a portion formed between the pair of third portions and extending to intersect the second axis when viewed in the third direction, and a portion formed between the pair of fourth portions and extending to intersect the second axis when viewed in the third direction. In such a manner, the rib portion extending to intersect the second axis is not formed in a region between the pair of third portions and a region between the pair of fourth portions which have a relatively large influence on the moment of inertia of the movable portion around the first axis, whereas the first extending portion and the second extending portion are formed in a region between the pair of first portions and a region between the pair of second portions, respectively, which have a relatively small influence, so that reliability can be ensured through the reinforcement of the rib portion while realizing good swinging of the movable portion through the suppression of an increase in the moment of inertia of the movable portion around the first axis. In addition, a decrease in the resonance frequency of the movable portion around the first axis can be suppressed by suppressing an increase in the moment of inertia of the movable portion around the first axis. Therefore, according to the mirror device, distortion of the mirror surface can be effectively suppressed, and reliability can be ensured while realizing good swinging of the movable portion.

[2] In the mirror device according to one aspect of the present disclosure, according to [1], “the first extending portion may be connected to the pair of first portions, and the second extending portion may be connected to the pair of second portions.” In this case, distortion of the movable portion can be more effectively suppressed. In addition, the rigidity of the first rib portion and the second rib portion can be increased, and damage to the rib portion or the peeling of the rib portion can be suppressed.

[3] In the mirror device according to one aspect of the present disclosure, according to [1] or [2], “the pair of first portions may be connected to each other on the side of the reference position, and the pair of second portions may be connected to each other on the side of the reference position.” In this case, the rigidity of the first rib portion and the second rib portion can be increased, and damage to the rib portion or the peeling of the rib portion can be suppressed.

[4] In the mirror device according to one aspect of the present disclosure, according to any one of [1] to [3], “the pair of third portions may be connected to each other on the side of the reference position, and the pair of fourth portions may be connected to each other on the side of the reference position.” In this case, the rigidity of the third rib portion and the fourth rib portion can be increased, and damage to the rib portion or the peeling of the rib portion can be suppressed.

[5] In the mirror device according to one aspect of the present disclosure, according to any one of [1] to [4], “the rib portion may include a reference portion disposed at the reference position when viewed in the third direction. The pair of first portions, the pair of second portions, the pair of third portions, and the pair of fourth portions may be connected to the reference portion.” In this case, the rigidity of the rib portion can be increased, and damage to the rib portion or the peeling of the rib portion can be suppressed.

[6] In the mirror device according to one aspect of the present disclosure, according to any one of [1] to [5], “when viewed in the third direction, the first extending portion may be curved to be convex toward the one side in the first direction, and the second extending portion may be curved to be convex toward the other side in the first direction.” In this case, distortion of the body portion can be more effectively suppressed.

[7] In the mirror device according to one aspect of the present disclosure, according to any one of [1] to [6], “the first extending portion may be connected to end portions on an opposite side of the pair of first portions from the reference position, and the second extending portion may be connected to end portions on an opposite side of the pair of second portions from the reference position.” In this case, distortion of the body portion can be more effectively suppressed.

[8] In the mirror device according to one aspect of the present disclosure, according to any one of [1] to [7], “each of the pair of first portions, the pair of second portions, the pair of third portions, and the pair of fourth portions may extend straight. When viewed in the direction perpendicular to the second surface, if an angle between the pair of first portions is θ1, an angle between the pair of second portions is θ2, an angle between the pair of third portions is θ3, and an angle between the pair of fourth portions is θ4, each of θ1 and θ2 may be larger than each of θ3 and θ4.” In this case, since the region between the pair of first portions and the region between the pair of second portions become wider, the first extending portion and the second extending portion can be lengthened, and as a result, distortion of the movable portion can be more effectively suppressed.

[9] In the mirror device according to one aspect of the present disclosure, according to [8], “the following relationships may be satisfied.”

$$\begin{matrix}θ3 < θ 1 < 3 \times θ 3 \\ θ4 < θ1 < 3 \times θ 4 \\ θ3 < θ2 < 3 \times θ 3 \\ θ4 < θ2 < 3 \times θ 4\end{matrix}$$

In this case, since the length of the first extending portion and the second extending portion can be made less than or equal to a predetermined length, distortion of the movable portion can be suppressed while suppressing an increase in the moment of inertia of the movable portion around the first axis.

[10] In the mirror device according to one aspect of the present disclosure, according to any one of [1] to [9], “each of a length of the pair of first portions and a length of the pair of second portions may be longer than each of a length of the pair of third portions and a length of the pair of fourth portions.” In this case, an increase in the moment of inertia of the movable portion around the first axis can be further suppressed.

[11] In the mirror device according to one aspect of the present disclosure, according to any one of [1] to [10], “the reference position may coincide with the center of the movable portion when viewed in the third direction.” In this case, the rib portion can be disposed on the movable portion in a well-balanced manner, and distortion of the movable portion can be effectively suppressed.

[12] In the mirror device according to one aspect of the present disclosure, according to [2], “when viewed in the third direction, an inner edge of the first extending portion may be smoothly connected to inner edges of the pair of first portions, and an inner edge of the second extending portion may be smoothly connected to inner edges of the pair of second portions.” The closer a portion on the movable portion is to an outer edge portion, the more likely distortion is to occur at the portion; however, with such a configuration as described [12], stress can be dispersed, and damage to the first rib portion and the second rib portion or the peeling of the first rib portion and the second rib portion can be suppressed.

[13] In the mirror device according to one aspect of the present disclosure, according to [4], “when viewed in the third direction, inner edges of the pair of third portions may be smoothly connected to each other, and inner edges of the pair of fourth portions may be smoothly connected to each other.” Since the rib portion is not formed in the region between the pair of third portions and the region between the pair of fourth portions, the third rib portion and the fourth rib portion are likely to become structurally weak, particularly, stress is likely to concentrate on the connection location between the pair of third portions and the connection location between the pair of fourth portions; however, with such a configuration as described in [13], stress can be dispersed, and damage to the third rib portion and the fourth rib portion or the peeling of the third rib portion and the fourth rib portion can be suppressed.

[14] In the mirror device according to one aspect of the present disclosure, according to any one of [1] to [10], “the movable portion may include a body portion including the first surface and the second surface, an ring-shaped portion surrounding the body portion with a gap interposed between the ring-shaped portion and the body portion when viewed in the third direction, and connected to the coupling portion, and a connection portion that connects the ring-shaped portion to the body portion. The mirror surface may be formed on the first surface of the body portion, and the rib portion may be formed on the second surface of the body portion.” In this case, since the movable portion is connected to the coupling portion via the ring-shaped portion, the occurrence that stress generated in the coupling portion during swinging of the movable portion is transmitted to the movable portion can be suppressed, and dynamic distortion of the movable portion can be suppressed. In addition, the transmission of the stress to the rib portion can be suppressed, and damage to the rib portion or the peeling of the rib portion can be suppressed.

[15] In the mirror device according to one aspect of the present disclosure, according to [14], “the movable portion may include a first connection portion and a second connection portion as the connection portion, the first connection portion may be disposed on the one side in the second direction with respect to the body portion, and the second connection portion may be disposed on the other side in the second direction with respect to the body portion. The first connection portion may include a pair of first connection regions separated from each other by a space, each of the pair of first connection regions may be connected to the body portion and the ring-shaped portion, the second connection portion may include a pair of second connection regions separated from each other by a space, and each of the pair of second connection regions may be connected to the body portion and the ring-shaped portion. The pair of third portions may extend toward the pair of respective first connection regions, and the pair of fourth portions may extend toward the pair of respective second connection regions.” In this case, since the first connection portion includes the pair of first connection regions and the second connection portion includes the pair of second connection regions, the occurrence that stress generated in the coupling portion during swinging of the movable portion is transmitted to the movable portion and the rib portion can be further suppressed. In addition, rigidity is likely to be low in the vicinities of the first connection regions and the second connection regions; however, since the pair of third portions extend toward the pair of respective first connection regions and the pair of fourth portions extend toward the pair of respective second connection regions, rigidity in the vicinities of the first connection regions and the second connection regions can be increased.

[16] In the mirror device according to one aspect of the present disclosure, according to [15], “when viewed in the third direction, the pair of third portions may not reach the pair of first connection regions, and the pair of fourth portions may not reach the pair of second connection regions.” Since relatively large dynamic distortion occurs in the ring-shaped portion or the first connection regions and the second connection regions, with such a configuration, damage to the third rib portion and the fourth rib portion or the peeling of the third rib portion and the fourth rib portion can be suppressed.

[17] In the mirror device according to one aspect of the present disclosure, according to [16], “a distance between the pair of third portions and the pair of first connection regions may be smaller than a maximum width of each of the pair of first connection regions, and a distance between the pair of fourth portions and the pair of second connection regions may be smaller than a maximum width of each of the pair of second connection regions.” In this case, rigidity in the vicinities of the first connection regions and the second connection regions can be increased.

According to one aspect of the present disclosure, it is possible to provide the mirror device capable of effectively suppressing distortion of the mirror surface and ensuring reliability while realizing good swinging of the movable portion.

### BRIEF DESCRIPTION OF THE DRAWINGS

FIG. 1 is a plan view of a mirror device according to an embodiment.

FIG. 2 is a bottom view of the mirror device.

FIG. 3 is a partial enlarged view of FIG. 2.

FIG. 4 is a cross-sectional view taken along line IV-IV in FIG. 3.

FIG. 5 is a perspective view of a peripheral portion of a first movable portion.

FIG. 6 is a partial enlarged view of FIG. 3.

FIGS. 7A and 7B are views showing a first modification example and a second modification example.

FIGS. 8A and 8B are views showing a third modification example and a fourth modification example.

FIGS. 9A and 9B are views showing a fifth modification example and a sixth modification example.

FIGS. 10A and 10B are views showing a seventh modification example and an eighth modification example.

FIGS. 11A and 11B are views showing a ninth modification example and a tenth modification example.

FIGS. 12A and 12B are views showing a first comparative example and a second comparative example.

FIGS. 13A and 13B are views showing a third comparative example and a fourth comparative example.

### DETAILED DESCRIPTION

Hereinafter, an embodiment of the present disclosure will be described in detail with reference to the drawings. In the following description, the same reference signs are used for the same or equivalent elements, and duplicate descriptions will be omitted.

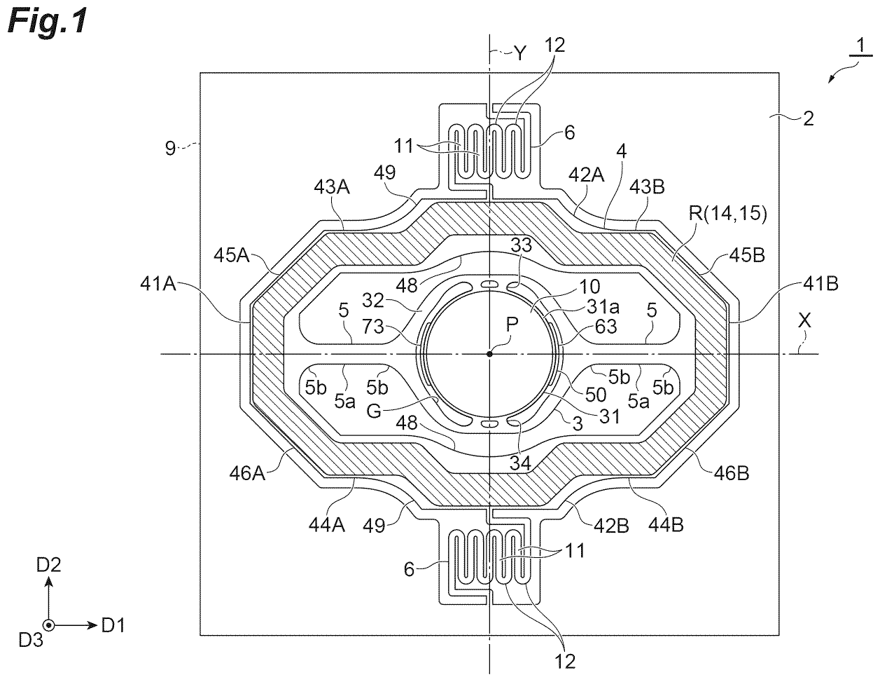

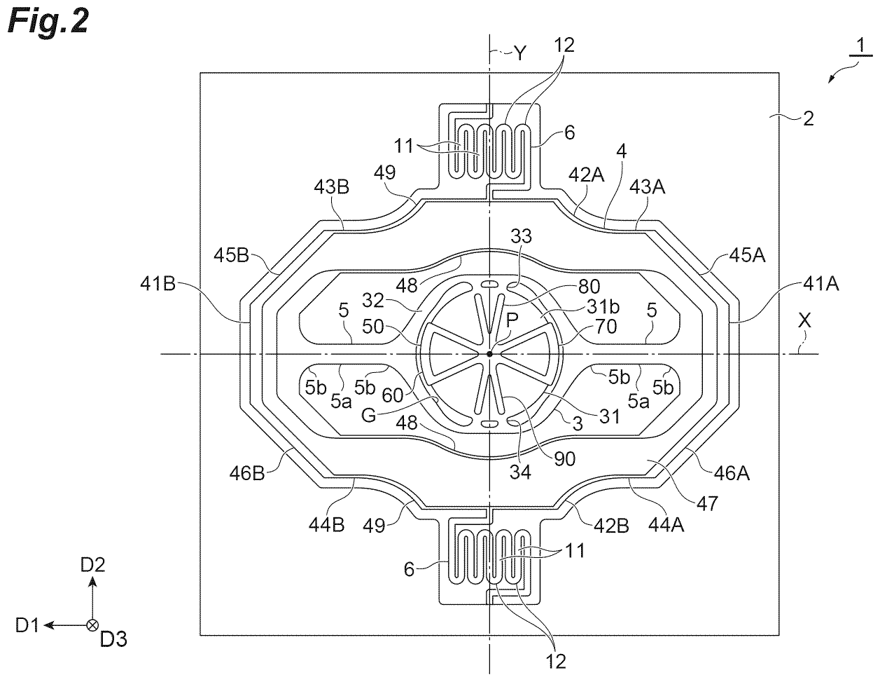

As shown in FIGS. 1 to 4, a mirror device 1 includes a support portion 2, a first movable portion 3, a second movable portion 4, a pair of first torsion bars (first coupling portions) 5, a pair of second torsion bars (second coupling portions) 6, and a magnetic field generation portion 9. In the mirror device 1, the first movable portion 3 having a mirror surface 10 swings around each of an X-axis (first axis) and a Y-axis (second axis perpendicular to the first axis) orthogonal to each other. The mirror device 1 can be used, for example, in an optical switch for optical communication, an optical scanner, and the like. In the following description, a direction parallel to the X-axis is a direction D1 (first direction), a direction parallel to the Y-axis is a direction D2 (second direction), and a direction perpendicular to both the direction D1 and the direction D2 is a direction D3 (third direction). Incidentally, in FIG. 2, the illustration of the magnetic field generation portion 9 is omitted.

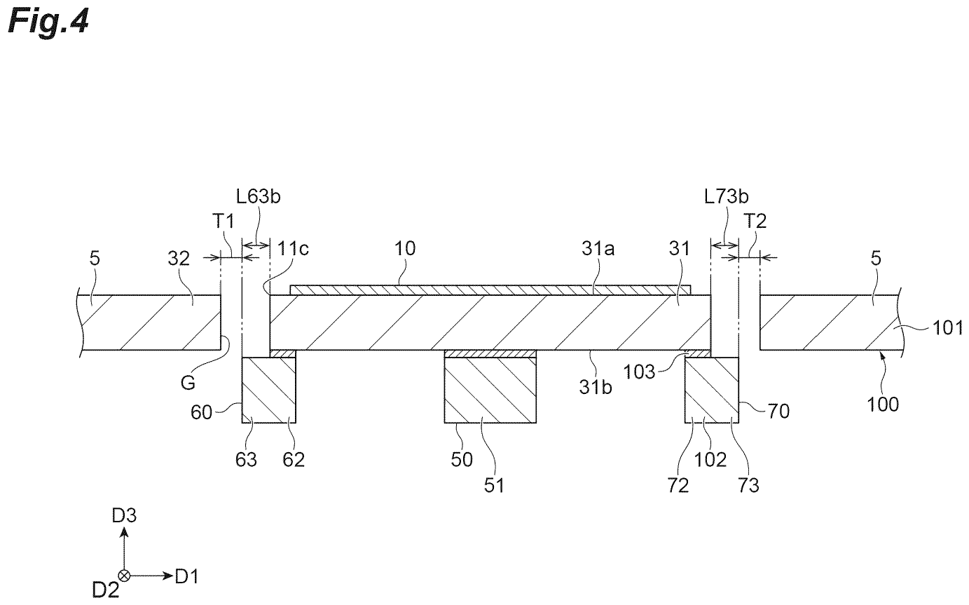

The support portion 2, the first movable portion 3, the second movable portion 4, the pair of first torsion bars 5, and the pair of second torsion bars 6 are integrally formed, for example, from a silicon on insulator (SOI) substrate 100 (refer to FIG. 4). Namely, the mirror device 1 is configured as a MEMS device manufactured by processing a semiconductor substrate using MEMS technology (patterning, etching, and the like). The SOI substrate 100 includes a first semiconductor layer 101; a second semiconductor layer 102; and an insulating layer 103 disposed between the first semiconductor layer 101 and the second semiconductor layer 102. For example, the first semiconductor layer 101 and the second semiconductor layer 102 are made of silicon, and the insulating layer 103 is made of silicon dioxide.

The magnetic field generation portion 9 is made up of, for example, a plurality of permanent magnets arranged in a Halbach array. The magnetic field generation portion 9 generates a magnetic field acting on coils 14 and 15 to be described later. The support portion 2 has, for example, a quadrangular outer shape in a plan view (when viewed in the direction D3), and is formed in a frame shape. The support portion 2 is formed from the first semiconductor layer 101, the second semiconductor layer 102, and the insulating layer 103. The support portion 2 is disposed on one side of the magnetic field generation portion 9 in the direction D3. The support portion 2 supports the first movable portion 3, the second movable portion 4, and the like. The first movable portion 3 is disposed inside the support portion 2 in a state where the first movable portion 3 is separated from the magnetic field generation portion 9. The first movable portion 3 has a shape that is symmetrical with respect to each of the X-axis and the Y-axis in a plan view. The first movable portion 3 includes a body portion 31, an ring-shaped portion 32, a first connection portion 33, and a second connection portion 34. The body portion 31, the ring-shaped portion 32, the first connection portion 33, and the second connection portion 34 are formed from the first semiconductor layer 101.

The body portion 31 is formed, for example, in a circular shape in a plan view. A center P (center of gravity) of the body portion 31 (center of the first movable portion 3) in a plan view coincides with the intersection point of the X-axis and the Y-axis. Namely, the X-axis and the Y-axis pass through the center P. The body portion 31 has a first surface 31a and a second surface 31b opposite to the first surface 31a (refer to FIG. 4). The first surface 31a is a surface on the one side in the direction D3, and is a surface opposite to the magnetic field generation portion 9. In this example, the first surface 31a and the second surface 31b are flat surfaces parallel to each other, and extend perpendicularly to the direction D3. The mirror surface 10 having a circular shape is formed on the first surface 31a. The mirror surface 10 is formed, for example, of a surface of a metal film made of aluminum. The mirror surface 10 is formed on substantially the entirety of the first surface 31a, but may be formed on a part of the first surface 31a.

The ring-shaped portion 32 is formed in a ring shape in a plan view, and surrounds the body portion 31 with a gap G interposed therebetween. The ring-shaped portion 32 has, for example, a substantially octagonal outer shape and a substantially circular inner shape in a plan view. The ring-shaped portion 32 is connected to the pair of first torsion bars 5 on the X-axis.

The first connection portion 33 is disposed on one side in the direction D2 with respect to the body portion 31 (upper side in FIG. 1), and the second connection portion 34 is disposed on the other side in the direction D2 with respect to the body portion 31 (lower side in FIG. 1). Each of the first connection portion 33 and the second connection portion 34 connects the ring-shaped portion 32 to the body portion 31. The gap G (space) is formed between the ring-shaped portion 32 and the body portion 31 except for locations where the first connection portion 33 and the second connection portion 34 are disposed. In a plan view, the gap G includes a portion at which the width (width in a direction perpendicular to an extending direction of the gap G) becomes wider as the gap G extends from an X-axis side toward a first connection portion 33 (second connection portion 34) side in the direction D2. In addition, in a plan view, the ring-shaped portion 32 includes a portion at which the width (width in a direction perpendicular to an extending direction of the ring-shaped portion 32) becomes narrower as the ring-shaped portion 32 extends from the X-axis side toward the first connection portion 33 (second connection portion 34) side in the direction D2. Since the width of the ring-shaped portion 32 is gradually narrowed as the ring-shaped portion 32 extends from the X-axis side toward the first connection portion 33 (second connection portion 34) side, dynamic distortion that occurs in the first torsion bars 5 and the second torsion bars 6 during swinging and that is transmitted to the ring-shaped portion 32, or static distortion that occurs due to the formation of a coil or the like in the second movable portion 4 and that is transmitted to the ring-shaped portion 32 via the first torsion bars 5 can be suitably relieved by the ring-shaped portion 32. Note that unlike the torsion bars (coupling portions) that couple the movable portions so as to be swingable around the axes, the first connection portion 33 and the second connection portion 34 are not intended to swingably couple the body portion 31 to the ring-shaped portion 32.

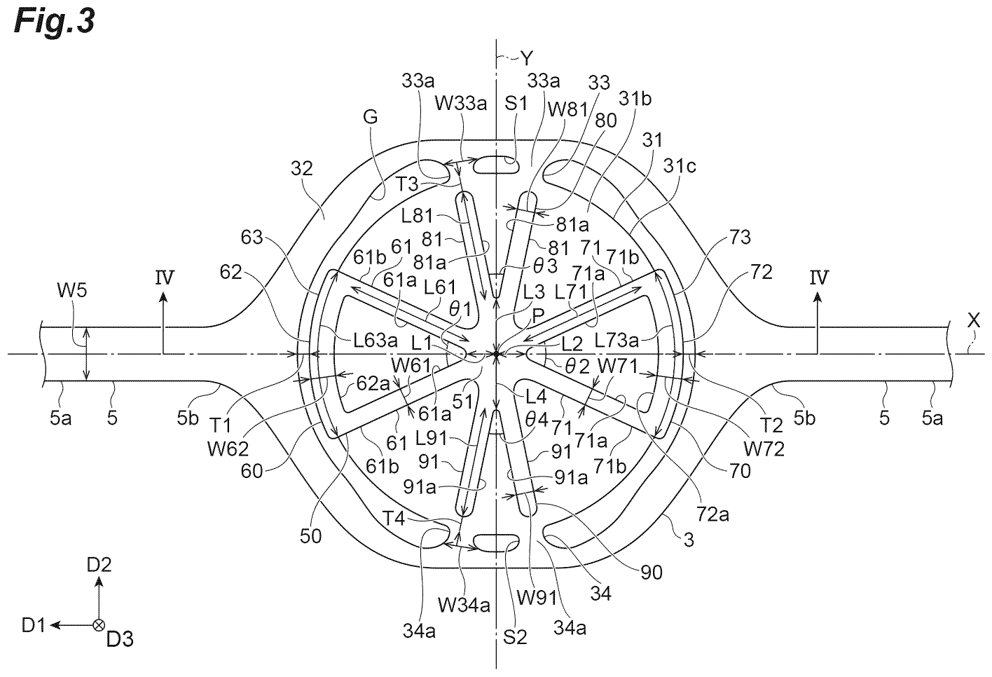

As shown in FIG. 3, the first connection portion 33 includes a pair of first connection regions 33a separated from each other by a space S1 (through-hole). In this example, the space S1 is located on the Y-axis, and the pair of first connection regions 33a face each other with the Y-axis interposed therebetween in the direction D1. Each of the first connection regions 33a is connected to the body portion 31 and the ring-shaped portion 32. The second connection portion 34 includes a pair of second connection regions 34a separated from each other by a space S2 (through-hole). In this example, the space S2 is located on the Y-axis, and the pair of second connection regions 34a face each other with the Y-axis interposed therebetween in the direction D1. Each of the second connection regions 34a is connected to the body portion 31 and the ring-shaped portion 32.

The second movable portion 4 is formed in a frame shape, and is disposed inside the support portion 2 to surround the first movable portion 3 in a state where the second movable portion 4 is separated from the magnetic field generation portion 9. The second movable portion 4 includes a pair of first connection portions 41A and 41B, a pair of second connection portions 42A and 42B, a pair of first linear portions 43A and 43B, a pair of second linear portions 44A and 44B, a pair of third linear portions 45A and 45B, and a pair of fourth linear portions 46A and 46B. Each of these portions is formed from the first semiconductor layer 101. The second movable portion 4 has a shape that is symmetrical with respect to each of the X-axis and the Y-axis in a plan view.

The first connection portions 41A and 41B are located on both sides of the first movable portion 3 in the direction D1, and extend along the direction D2. The second connection portions 42A and 42B are located on both sides of the first movable portion 3 in the direction D2, and extend along the direction D1. An inner edge of each of the second connection portions 42A and 42B in a plan view includes a concave portion 48 recessed in the direction D2, and an outer edge of each of the second connection portions 42A and 42B in a plan view includes a convex portion 49 protruding in the direction D2. The concave portion 48 and the convex portion 49 are located on the Y-axis in a plan view.

The first linear portions 43A and 43B are located on both sides of the second connection portion 42A in the direction D1, and extend along the direction D1 to be connected to the second connection portion 42A. The second linear portions 44A and 44B are located on both sides of the second connection portion 42B in the direction D1, and extend along the direction D1 to be connected to the second connection portion 42B.

The third linear portions 45A and 45B are located opposite to the second connection portion 42A with respect to the first linear portions 43A and 43B, respectively, and are connected to the first linear portions 43A and 43B and the first connection portions 41A and 41B, respectively. The fourth linear portions 46A and 46B are located opposite to the second connection portion 42B with respect to the second linear portions 44A and 44B, respectively, and are connected to the second linear portions 44A and 44B and the first connection portions 41A and 41B, respectively. The third linear portions 45A and 45B and the fourth linear portions 46A and 46B extend along a direction inclined at 45 degrees with respect to the X-axis and the Y-axis in a plan view.

A rib portion 47 is formed on surfaces on a magnetic field generation portion 9 side of the connection portions 41A to 42B and the linear portions 43A to 46B (refer to FIG. 2). The rib portion 47 is formed from the second semiconductor layer 102 and the insulating layer 103. The rib portion 47 extends in an annular shape to surround the first movable portion 3 in a plan view. A width of the rib portion 47 on the first connection portions 41A and 41B and the linear portions 45A to 46B is narrower than a width of the rib portion 47 on the second connection portions 42A and 42B and the linear portions 43A to 44B.

The first torsion bars 5 and the second torsion bars 6 are formed from the first semiconductor layer 101. The pair of first torsion bars 5 are disposed on both sides of the first movable portion 3 on the X-axis. The first torsion bars 5 couple the first movable portion 3 (ring-shaped portion 32) to the second movable portion 4 on the X-axis such that the first movable portion 3 is swingable around the X-axis (with the X-axis as a center line). In addition, the first torsion bars 5 are connected to the support portion 2 via the second movable portion 4 and the second torsion bars 6. Namely, the first torsion bars 5 can also be deemed to couple the first movable portion 3 to the support portion 2 such that the first movable portion 3 is swingable around the X-axis. The pair of first torsion bars 5 are connected to the second movable portion 4 at the first connection portions 41A and 41B, respectively. In this example, the first torsion bars 5 are formed in a plate shape extending along a plane parallel to the mirror surface 10, and are torsionally deformed when the first movable portion 3 swings around the X-axis.

Each of the first torsion bars 5 includes a linear portion 5a extending along the X-axis and having a constant width, and a pair of widened portions 5b connected to both ends of the linear portion 5a. The first torsion bars 5 is connected to the first movable portion 3 at one widened portion 5b, and is connected to the second movable portion 4 at the other widened portion 5b. In a plan view, the width of the one widened portion 5b becomes wider as the one widened portion 5b approaches the first movable portion 3, and the width of the other widened portion 5b becomes wider as the other widened portion 5b approaches the second movable portion 4. Each of the widened portions 5b is provided to relieve stress acting on a connection location between the first torsion bar 5 and the first movable portion 3 or the second movable portion 4 when the first movable portion 3 swings around the X-axis. Namely, since the widened portions 5b are provided, stress when the first movable portion 3 swings around the X-axis is relieved by the widened portions 5b, and stress acting on the first movable portion 3 (ring-shaped portion 32) is reduced, so that dynamic distortion in the body portion 31 can be suppressed. Incidentally, at least one of the pair of widened portions 5b may not be provided.

The pair of second torsion bars 6 are disposed on both sides of the second movable portion 4 on the Y-axis. The second torsion bars 6 couple the second movable portion 4 to the support portion 2 on the Y-axis such that the second movable portion 4 is swingable around the Y-axis (with the Y-axis as a center line). The pair of second torsion bars 6 are connected to the second movable portion 4 at the second connection portions 42A and 42B, respectively. The second torsion bars 6 are torsionally deformed when the second movable portion 4 swings around the Y-axis. In this example, the second torsion bars 6 extend in a meandering manner in a plan view. Each of the second torsion bars 6 includes a plurality of linear portions 11 and a plurality of folded portions 12. The plurality of linear portions 11 extend along the direction D2, and are disposed side by side in the direction D1. The plurality of folded portions 12 alternately couple both ends of the linear portions 11 adjacent to each other.

In this example, for the purpose of increasing the resonance frequency around the X-axis, a spring constant of the first torsion bars 5 is set to be larger than a spring constant of the second torsion bars 6. When the cross-sectional area (cross-sectional area in a cross-section perpendicular to an extending direction) of each torsion bar is increased, the spring constant increases. In this example, the first torsion bars 5 and the second torsion bars 6 have substantially the same thickness in the direction D3, whereas the first torsion bars 5 has a larger width (width in a direction perpendicular to the extending direction), and as a result, the cross-sectional area of the first torsion bars 5 is increased.

The mirror device 1 further includes a pair of the coils 14 and 15. Each of the coils 14 and 15 is provided in the second movable portion 4 to surround the first movable portion 3, and extends in a spiral shape in a plan view. The coils 14 and 15 are disposed along a plane including the X-axis and the Y-axis. Each of the coils 14 and 15 is wound around the first movable portion 3 a plurality of times. For example, the coils 14 and 15 are alternately arranged in a width direction of the second movable portion 4 in a plan view. The coils 14 and 15 are configured, for example, as Damascene wirings embedded in the second movable portion 4.

In FIG. 1, a disposition region R where the coils 14 and 15 are disposed is shown by hatching. The coils 14 and 15 extend in the connection portions 41A to 42B and the linear portions 43A to 46B of the second movable portion 4 along extending directions thereof. For example, each of the coils 14 and 15 is electrically connected to an electrode pad on the support portion 2 via wirings extending through the second torsion bars 6, and is electrically connected to a drive source or the like disposed outside the mirror device 1. The coils 14 and 15 can be used not only as drive coils, but also as monitor coils for checking the vibration state of the device by measuring a counter-electromotive force generated in the coils 14 and 15.

In the mirror device 1 configured as described above, when a drive signal for linear motion is input to the coil 14, a Lorentz force acts on the coil 14 due to interaction with a magnetic field generated by the magnetic field generation portion 9. By using the balance between the Lorentz force and the elastic force of the second torsion bars 6, the first movable portion 3 (mirror surface 10) can be linearly moved around the Y-axis together with the second movable portion 4.

On the other hand, when a drive signal for resonance motion is input to the coil 15, a Lorentz force acts on the coil 15 due to interaction with a magnetic field generated by the magnetic field generation portion 9. By using the resonance of the first movable portion 3 at a resonance frequency in addition to the Lorentz force, the first movable portion 3 (mirror surface 10) can be resonantly moved around the X-axis. Specifically, when a drive signal with a frequency equal to the resonance frequency of the first movable portion 3 around the X-axis is input to the coil 15, the second movable portion 4 vibrates slightly around the X-axis at the frequency. The vibration is transmitted to the first movable portion 3 via the first torsion bars 5, so that the first movable portion 3 can swing around the X-axis at the frequency.

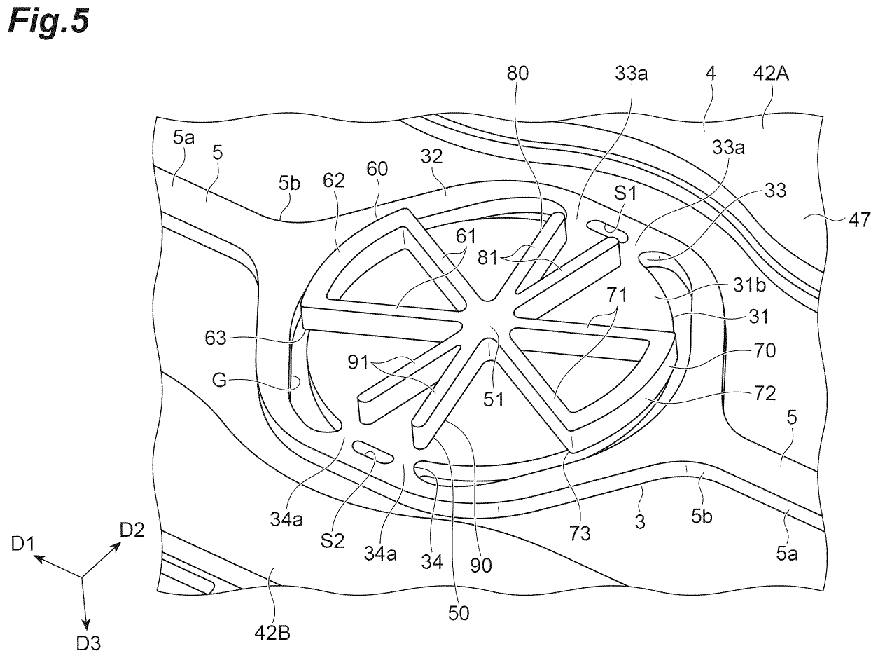

As shown in FIGS. 2 to 6, a rib portion 50 (rib) is formed on the second surface 31b of the body portion 31 of the first movable portion 3. The rib portion 50 is a reinforcing rib for reinforcing the first movable portion 3, and is configured as a reinforcing structure extending along a predetermined direction. The rib portion 50 is formed from the second semiconductor layer 102 and the insulating layer 103. In this example, the rib portion 50 has a shape that is symmetrical with respect to each of the X-axis and the Y-axis in a plan view. The rib portion 50 includes a central portion 51, a first rib portion 60, a second rib portion 70, a third rib portion 80, and a fourth rib portion 90.

The central portion 51 is a reference portion disposed at a reference position in a plan view. In this example, the reference position coincides with the center P of the body portion in a plan view, and the central portion 51 is disposed on the center P. In the present embodiment, the central portion 51 has an elongated shape in the direction D2 in a plan view. The central portion 51 may be formed such that a width in the direction D1 and a width in the direction D2 are substantially the same. A distance L1 from the center P of the central portion 51 to a location where inner edges 61a of a pair of first portions 61 of the first rib portion 60 to be described later are connected is larger than a width W61 of the first portions 61. Accordingly, sufficient rigidity can be ensured at the central portion 51, and damage to the rib portion 50 or the peeling of the rib portion 50 from the body portion 31 can be prevented. The same applies to a second rib portion 70 side. Namely, a distance L2 from the center P of the central portion 51 to a location where inner edges 71a of a pair of second portions 71 of the second rib portion 70 to be described later are connected is larger than a width W71 of the second portions 71. In addition, a distance L3 from the center P of the central portion 51 to a location where inner edges 81a of a pair of third portions 81 of the third rib portion 80 to be described later are connected is larger than a width W81 of the third portions 81. Even with this configuration, sufficient rigidity can be ensured at the central portion 51, and damage to the rib portion 50 or the peeling of the rib portion 50 from the body portion 31 can be prevented. The same applies to a fourth rib portion 90 side. Namely, a distance L4 from the center P of the central portion 51 to a location where inner edges 91a of a pair of fourth portions 91 of the fourth rib portion 90 to be described later are connected is larger than a width W91 of the fourth portions 91.

The first rib portion 60 includes the pair of first portions 61 and a first extending portion 62 (first connecting portion). The pair of first portions 61 extend from the central portion 51 (from the side of the center P that is a reference position) toward one side (left side in FIG. 3) in the direction D1, and face each other with the X-axis interposed therebetween in the direction D2. The pair of first portions 61 extend straight along directions inclined with respect to the direction D1 and the direction D2 in a plan view. In this example, the pair of first portions 61 extend along a radial direction of a circle centered on the center P.

The pair of first portions 61 are connected to each other at the central portion 51 (at the side of the center P that is a reference position). In this example, the pair of first portions 61 are connected to each other via the central portion 51 (integrated). In a plan view, the inner edges 61a of the pair of first portions 61 are smoothly connected to each other. The fact that “edges A and B are smoothly connected” means that there is no sharp location (for example, the vertex of a corner (including all cases of an acute angle, a right angle, and an obtuse angle)) between the edges A and B and the edges A and B are connected such that the curvature is continuous between the edges A and B. In this example, the inner edges 61a are smoothly connected by an outer edge of the central portion 51 formed in an arc shape.

The first extending portion 62 extends between the pair of first portions 61 in a plan view. In this example, the first extending portion 62 extends to intersect the X-axis in a plan view, and is connected to the pair of first portions 61. In more detail, the first extending portion 62 is connected to end portions 61b on an opposite side of the pair of first portions 61 from the central portion 51. In a plan view, an inner edge 62a of the first extending portion 62 is smoothly connected to the inner edges 61a of the pair of first portions 61. In this example, an R portion that is curved in an arc shape is formed between the inner edges 61a and 62a, and accordingly, the inner edges 61a and 62a are smoothly connected. The first extending portion 62 extends along an outer edge 31c of the body portion 31 of the first movable portion 3 in a plan view. In addition, the first extending portion 62 is curved to be convex toward the one side (side opposite to the central portion 51) in the direction D1 in a plan view. In this example, the outer edge 31c has an arc shape, and the first extending portion 62 is formed in an arc shape that is convex toward the one side in the direction D1.

A width W62 of the first extending portion 62 is wider than the width W61 of each of the first portions 61. The width W61 of the first portion 61 is a width of the first portion 61 along a direction perpendicular to an extending direction (direction from the center P toward the end portion 61b) of the first portion 61 in a plan view. The width W62 of the first extending portion 62 is a width of the first extending portion 62 along a direction perpendicular to an extending direction (direction along the outer edge 31c) of the first extending portion 62 in a plan view. These points also apply to the width W71 of the second portions 71 and a width W72 of a second extending portion 72 to be described later, as well as the width W81 of the third portions 81 and the width W91 of the fourth portions 91 described above.

Each of the width W61 of the first portions 61 and the width W71 of the second portions 71 is more than or equal to each of the width W81 of the third portions 81 and the width W91 of the fourth portions 91. Accordingly, the strength of the first rib portion 60 and the second rib portion 70 can be sufficiently ensured while suppressing an increase in the moment of inertia around the X-axis. It is more preferable that each of the width W61 and the width W71 is larger than each of the width W81 and the width W91. In addition, each of the width W62 of the first extending portion 62 and the width W72 of the second extending portion 72 is more than or equal to each of the width W81 of the third portions 81 and the width W91 of the fourth portions 91. Accordingly, the strength of the first rib portion 60 and the second rib portion 70 can be sufficiently ensured while suppressing an increase in the moment of inertia around the X-axis. It is more preferable that each of the width W62 and the width W72 is larger than each of the width W81 and the width W91.

The first extending portion 62 includes a protrusion portion 63 protruding outward (side opposite to the center P) from the outer edge 31c (boundary between the body portion 31 and the gap G) of the body portion 31 in a plan view. Namely, the protrusion portion 63 is located outside the outer edge 31c in a plan view. An inner portion (portion other than the protrusion portion 63) of the first extending portion 62 does not protrude outward from the outer edge 31c. In a plan view, the entirety of a region surrounded by the first extending portion 62, the pair of first portions 61, and the central portion 51 overlaps the body portion 31. The region is a region where the rib portion 50 is not formed (region with no rib). Since the region where the rib portion 50 is not formed is provided on the body portion 31 in such a manner, the strength of the rib portion 50 can be improved while suppressing an increase in the moment of inertia in the first movable portion 3.

The protrusion portion 63 extends along the outer edge 31c of the body portion 31. In this example, the protrusion portion 63 is provided over the entirety of the first extending portion 62 in the extending direction (direction along the outer edge 31c) of the first extending portion 62, and is formed in an arc shape that is convex toward the one side (side opposite to the central portion 51) in the direction D1. Namely, the protrusion portion 63 is provided to extend between the pair of first portions 61 in the direction along the outer edge 31c, and protrudes outward from the outer edge 31c on the X-axis (intersects the X-axis in a plan view). The protrusion portion 63 can also be deemed to extend along the outer edge 31c from the X-axis toward the one side and the other side in the direction D2. The protrusion portion 63 overlaps the gap G formed between the body portion 31 and the ring-shaped portion 32 of the first movable portion 3 in a plan view. The protrusion portion 63 is not in contact with portions other than the body portion 31 (for example, the ring-shaped portion 32, the first torsion bars 5, the first connection portion 33, the second connection portion 34, and the like). Namely, in this example, the protrusion portion 63 is a portion floating in space without being supported by the portions other than the body portion 31. The protrusion portion 63 does not overlap the ring-shaped portion 32 in a plan view (does not reach the ring-shaped portion 32), and there is a gap between the protrusion portion 63 and the ring-shaped portion 32 in a plan view.

A distance T1 between the protrusion portion 63 and the ring-shaped portion 32 on the X-axis is smaller than a minimum width W5 of the first torsion bars 5 in the direction D2. A length L63a of the protrusion portion 63 along the outer edge 31c of the body portion 31 is larger than the minimum width W5 of the first torsion bars 5 in the direction D2. The length L63a is larger than the width W62 of the first extending portion 62. The length L63a is larger than the distance T1. The length L63a is larger than a maximum width W33a of the first connection regions 33a that connect the ring-shaped portion 32 and the body portion 31. The length L63a is larger than a maximum width of the entirety of the first connection portion 33 (region formed by the pair of first connection regions 33a and the space S1). A protrusion length L63b of the protrusion portion 63 from the outer edge 31c of the body portion 31 (refer to FIG. 4) is smaller than the minimum width W5 of the first torsion bars 5 in the direction D2. The width of the first torsion bars 5 is a width of the first torsion bars 5 along the direction (in this example, the direction D2) perpendicular to the extending direction (in this example, the direction D1) of the first torsion bars 5 in a plan view. The protrusion length L63b is a maximum protrusion length (maximum width) of the protrusion portion 63 in a direction (in this example, a radial direction of a circle centered on the center P) perpendicular to an extending direction (in this example, a circumferential direction of the circle centered on the center P) of the outer edge 31c in a plan view. Namely, when the outer edge 31c has a curvature, the extending direction of the outer edge 31c is a tangential direction. This point also applies to a protrusion length L73b of a protrusion portion 73 to be described later.

The second rib portion 70 has a shape that is symmetrical to the first rib portion 60 with respect to the Y-axis. The second rib portion 70 includes the pair of second portions 71 and the second extending portion 72 (second connecting portion). The pair of second portions 71 extend from the central portion 51 (from the side of the center P that is a reference position) toward the other side (right side in FIG. 3) in the direction D1, and face each other with the X-axis interposed therebetween in the direction D2. The second portions 71 extend straight along directions inclined with respect to the direction D1 and the direction D2 in a plan view. In this example, the pair of second portions 71 extend along a radial direction of a circle centered on the center P. In a plan view, one second portion 71 (the second portion 71 on the upper side in FIG. 3) is located on the same straight line as one first portion 61 (the first portion 61 on the lower side in FIG. 3) of the first rib portion 60, and the other second portion 71 (the second portion 71 on the lower side in FIG. 3) is located on the same straight line as the other first portion 61 (the first portion 61 on the upper side in FIG. 3) of the first rib portion 60. The first rib portion 60 and the second rib portion 70 as a whole have a ribbon shape in a plan view.

The pair of second portions 71 are connected to each other at the central portion 51 (at the side of the center P that is a reference position). In this example, the pair of second portions 71 are connected to each other via the central portion 51 (integrated). In a plan view, the inner edges 71a of the pair of second portions 71 are smoothly connected to each other. In this example, the inner edges 71a are smoothly connected by the outer edge of the central portion 51 formed in an arc shape.

The second extending portion 72 extends between the pair of second portions 71 in a plan view. In this example, the second extending portion 72 extends to intersect the X-axis in a plan view, and is connected to the pair of second portions 71. In more detail, the second extending portion 72 is connected to end portions 71b on an opposite side of the pair of second portions 71 from the central portion 51. In a plan view, an inner edge 72a of the second extending portion 72 is smoothly connected to the inner edges 71a of the pair of second portions 71. In this example, an R portion that is curved in an arc shape is formed between the inner edges 71a and 72a, and accordingly, the inner edges 71a and 72a are smoothly connected. The second extending portion 72 extends along the outer edge 31c of the body portion 31 of the first movable portion 3 in a plan view. In addition, the second extending portion 72 is curved to be convex toward the other side (side opposite to the central portion 51) in the direction D1 in a plan view. In this example, the outer edge 31c has an arc shape, and the second extending portion 72 is formed in an arc shape that is convex toward the other side in the direction D1.

The width W72 of the second extending portion 72 is wider than the width W71 of each of the second portions 71. The second extending portion 72 includes the protrusion portion 73 protruding outward (side opposite to the center P) from the outer edge 31c of the body portion 31 in a plan view. Namely, the protrusion portion 73 is located outside the outer edge 31c in a plan view. An inner portion (portion other than the protrusion portion 73) of the second extending portion 72 does not protrude outward from the outer edge 31c. In a plan view, the entirety of a region surrounded by the second extending portion 72, the pair of second portions 71, and the central portion 51 overlaps the body portion 31.

The protrusion portion 73 extends along the outer edge 31c of the body portion 31. In this example, the protrusion portion 73 is provided over the entirety of the second extending portion 72 in an extending direction (direction along the outer edge 31c) of the second extending portion 72, and is formed in an arc shape that is convex toward one side (side opposite to the central portion 51) in the direction D1. Namely, the protrusion portion 73 is provided to extend between the pair of second portions 71 in the direction along the outer edge 31c, and protrudes outward from the outer edge 31c on the X-axis (intersects the X-axis in a plan view). The protrusion portion 73 can also be deemed to extend along the outer edge 31c from the X-axis toward the one side and the other side in the direction D2. The protrusion portion 73 overlaps the gap G formed between the body portion 31 and the ring-shaped portion 32 of the first movable portion 3 in a plan view. The protrusion portion 73 is not in contact with portions other than the body portion 31 (for example, the ring-shaped portion 32, the pair of first torsion bars 5, the first connection portion 33, the second connection portion 34, and the like). Namely, in this example, the protrusion portion 73 is a portion floating in space without being supported by the portions other than the body portion 31.

A distance T2 between the protrusion portion 73 and the ring-shaped portion 32 on the X-axis is smaller than the minimum width W5 of the first torsion bars 5 in the direction D2. A length L73a of the protrusion portion 73 along the outer edge 31c of the body portion 31 is larger than the minimum width W5 of the first torsion bars 5 in the direction D2. The length L73a is larger than the width W72 of the second extending portion 72. The length L73a is larger than the distance T2. A protrusion length L73b of the protrusion portion 73 from the outer edge 31c of the body portion 31 (refer to FIG. 4) is smaller than the minimum width W5 of the first torsion bars 5 in the direction D2.

The third rib portion 80 includes the pair of third portions 81. The pair of third portions 81 extend from the central portion 51 (from the side of the center P that is a reference position) toward the one side (upper side in FIGS. 2 and 3) in the direction D2, and face each other with the Y-axis interposed therebetween in the direction D1. The third portions 81 extend straight along directions inclined with respect to the direction D1 and the direction D2 in a plan view. In this example, the pair of third portions 81 extend along a radial direction of a circle centered on the center P.

The pair of third portions 81 are connected to each other at the central portion 51 (at the side of the center P that is a reference position). In this example, the pair of third portions 81 are connected to each other via the central portion 51 (integrated). In a plan view, the inner edges 81a of the pair of third portions 81 are smoothly connected to each other. In this example, an R portion that is curved in an arc shape is formed between the inner edges 81a, and accordingly, the inner edges 81a are smoothly connected.

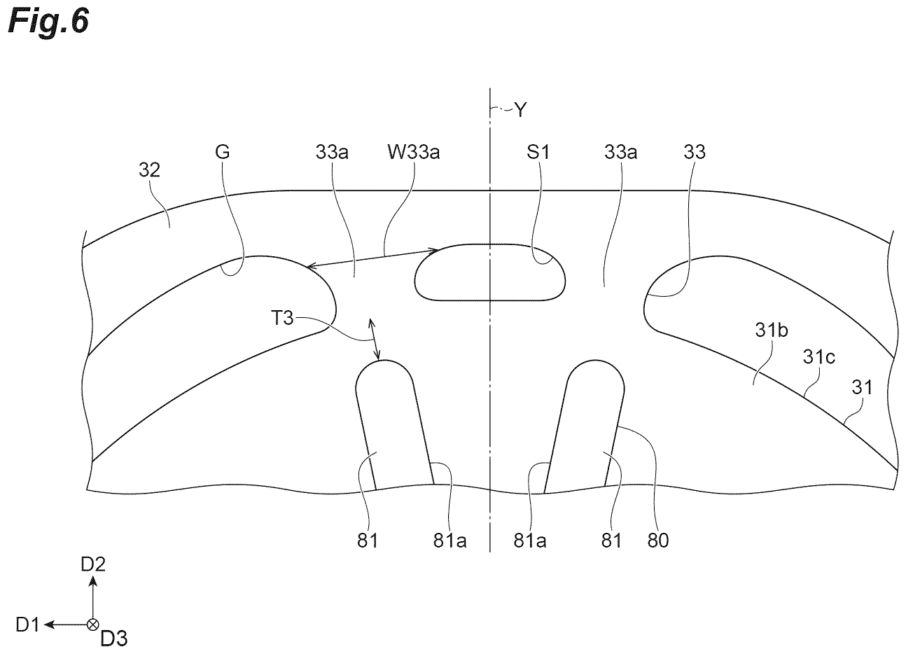

The pair of third portions 81 extend toward the pair of respective first connection regions 33a of the first connection portion 33 of the first movable portion 3. In a plan view, the third portions 81 do not reach the first connection regions 33a, and are separated from the first connection regions 33a. A distance T3 (shortest distance) between the third portions 81 and the first connection regions 33a is smaller than the maximum width W33a of the first connection regions 33a (refer to FIGS. 3 and 6). The maximum width W33a of the first connection regions 33a is a maximum width of the first connection regions 33a in directions perpendicular to directions in which the body portion 31 and the ring-shaped portion 32 are connected by the first connection regions 33a (extending directions of the first connection regions 33a). This point also applies to a maximum width W34a of the second connection regions 34a to be described later.

The rib portion 50 is not formed between the pair of third portions 81. Namely, the rib portion 50 does not include a portion formed between the pair of third portions 81. The fact that “the rib portion 50 does not include a portion formed between the pair of third portions 81” means, for example, that the rib portion 50 is not formed in a region between the pair of third portions 81 in a plan view. The central portion 51 does not correspond to “a portion formed between the pair of third portions 81”. These points also apply to the fourth portions 91 to be described later.

The fourth rib portion 90 includes the pair of fourth portions 91. The pair of fourth portions 91 extend from the central portion 51 (from the side of the center P that is a reference position) toward the other side (lower side in FIG. 3) in the direction D2, and face each other with the Y-axis interposed therebetween in the direction D1. The fourth portions 91 extend straight along directions inclined with respect to the direction D1 and the direction D2 in a plan view. In this example, the pair of fourth portions 91 extend along a radial direction of a circle centered on the center P. In a plan view, one fourth portion 91 (the fourth portion 91 on the left side in FIG. 3) is located on the same straight line as one third portion 81 (the third portion 81 on the right side in FIG. 3) of the third rib portion 80, and the other fourth portion 91 (the fourth portion 91 on the right side in FIG. 3) is located on the same straight line as the other third portion 81 (the third portion 81 on the left side in FIG. 3) of the third rib portion 80. The third rib portion 80 and the fourth rib portion 90 as a whole have an X shape in a plan view.

The pair of fourth portions 91 are connected to each other at the central portion 51 (at the side of the center P that is a reference position). In this example, the pair of fourth portions 91 are connected to each other via the central portion 51 (integrated). In a plan view, the inner edges 91a of the pair of fourth portions 91 are smoothly connected to each other. In this example, an R portion that is curved in an arc shape is formed between the inner edges 91a, and accordingly, the inner edges 91a are smoothly connected.

The pair of fourth portions 91 extend toward the pair of respective second connection regions 34a of the second connection portion 34 of the first movable portion 3. In a plan view, the fourth portions 91 do not reach the second connection regions 34a, and are separated from the second connection regions 34a. A distance T4 (shortest distance) between the fourth portions 91 and the second connection regions 34a is smaller than the maximum width W34a of the second connection regions 34a (refer to FIG. 3). The rib portion 50 is not formed between the pair of fourth portions 91. Namely, the rib portion 50 does not include a portion formed between the pair of fourth portions 91.

In the rib portion 50, the first portions 61, the second portions 71, the third portions 81, and the fourth portions 91 extend radially around the center P. The first portions 61, the second portions 71, the third portions 81, and the fourth portions 91 are different portions from one another (not shared with one another). Each of a length L61 of the first portions 61 and a length L71 of the second portions 71 is longer than each of a length L81 of the third portions 81 and a length L91 of the fourth portions 91. In this example, the lengths L61 and L71 are equal to each other, and the lengths L81 and L91 are equal to each other.

In a plan view, an angle between the pair of first portions 61 is θ1, an angle between the pair of second portions 71 is θ2, an angle between the pair of third portions 81 is θ3, and an angle between the pair of fourth portions 91 is θ4, the following relationships are satisfied.

$$\begin{matrix}θ3 < θ 1 < 3 \times θ 3 \\ θ4 < θ1 < 3 \times θ 4 \\ θ3 < θ2 < 3 \times θ 3 \\ θ4 < θ2 < 3 \times θ 4\end{matrix}$$

Namely, each of θ1 and θ2 is larger than each of θ3 and θ4, and is smaller than three times each of θ3 and θ4. In this example, θ1 and θ2 are equal to each other, and θ3 and θ4 are equal to each other. Preferably, θ1 and θ2 are larger than 30 degrees, and are smaller than 90 degrees. Preferably, θ3 and θ4 are larger than 10 degrees, and are smaller than 30 degrees.

One example of the dimensions of each portion is as follows. The distance T1 between the protrusion portion 63 and the ring-shaped portion 32 on the X-axis is equal to the distance T2 between the protrusion portion 73 and the ring-shaped portion 32 on the X-axis, and is approximately 10 μm to 100 μm. The width W61 of the first portions 61 is equal to the width W71 of the second portions 71, the width W81 of the third portions 81, and the width W91 of the fourth portions 91, and is approximately 10 μm to 100 μm. The width W62 of the first extending portion 62 is equal to the width W72 of the second extending portion 72, and is approximately 20 μm to 200 μm. The length L61 of the first portions 61 is equal to the length L71 of the second portions 71, and is approximately 100 μm to 1000 μm. The distance L1 from the center P of the central portion 51 to the location where the inner edges 61a of the pair of first portions 61 are connected is equal to the distance L2 from the center P to the location where the inner edges 71a of the pair of second portions 71 are connected, and is approximately 20 μm to 200 μm. The distance L3 from the center P to the location where the inner edges 81a of the pair of third portions 81 described later are connected is equal to the distance L4 from the center P to the location where the inner edges 91a of the pair of fourth portions 91 are connected, and is approximately 30 μm to 300 μm.

The length L63a of the protrusion portion 63 along the outer edge 31c of the body portion 31 is equal to the length L73a of the protrusion portion 73 along the outer edge 31c of the body portion 31, and is approximately 100 μm to 1000 μm. The maximum width W33a of the first connection regions 33a is equal to the maximum width W34a of the second connection regions 34a, and is approximately 20 μm to 200 μm. The distance T3 between the third portions 81 and the first connection regions 33a is equal to the distance T4 between the fourth portions 91 and the second connection regions 34a, and is approximately 10 μm to 100 μm. The protrusion length L63b of the protrusion portion 63 from the outer edge 31c of the body portion 31 is equal to the protrusion length L73b of the protrusion portion 73 from the outer edge 31c of the body portion 31, and is approximately 5 μm to 60 μm. A thickness of the first semiconductor layer 101 is approximately 20 μm to 200 μm. A thickness of the rib portion 50 is approximately 20 μm to 200 μm.

### [Functions and Effects]

In the mirror device 1, the rib portion 50 includes the first rib portion 60, the second rib portion 70, the third rib portion 80, and the fourth rib portion 90. The first rib portion 60 includes the pair of first portions 61 extending from the central portion 51 (from the side of the reference position) toward the one side in the direction D1 (direction parallel to the X-axis) and facing each other with the X-axis (first axis) interposed therebetween in the direction D2 (direction parallel to the Y-axis), and the first extending portion 62 extending between the pair of first portions 61 to intersect the X-axis in a plan view. The second rib portion 70 includes the pair of second portions 71 extending from the central portion 51 toward the other side in the direction D1 and facing each other with the X-axis interposed therebetween in the direction D2, and the second extending portion 72 extending between the pair of second portions 71 to intersect the X-axis in a plan view. The third rib portion 80 includes the pair of third portions 81 extending from the central portion 51 toward the one side in the direction D2 and facing each other with the Y-axis (second axis) interposed therebetween in the direction D1. The fourth rib portion 90 includes the pair of fourth portions 91 extending from the central portion 51 toward the other side in the direction D2 and facing each other with the Y-axis interposed therebetween in the direction D1. Accordingly, the rib portion 50 can be disposed on the first movable portion 3 in a well-balanced manner, and distortion of the first movable portion 3 (in other words, distortion of the mirror surface 10) can be effectively suppressed. On the other hand, when the first movable portion 3 swings, stress generated in the first torsion bars 5 may be transmitted to the rib portion 50, and from the viewpoint of preventing the rib portion 50 from being damaged or peeled off due to the stress, reinforcing the rib portion 50 can be considered. However, for example, when the rib portion 50 is reinforced simply by connecting rib portions, the moment of inertia of the first movable portion 3 around the X-axis may increase depending on the connection location. In this regard, in the mirror device 1, the first rib portion 60 includes the first extending portion 62 extending between the pair of first portions 61 to intersect the X-axis in a plan view (when viewed in the direction D3 perpendicular to the second surface 31b), and the second rib portion 70 includes the second extending portion 72 extending between the pair of second portions 71 to intersect the X-axis in a plan view, whereas the rib portion 50 does not include a portion formed between the pair of third portions 81 and a portion formed between the pair of fourth portions 91. In such a manner, the rib portion is not formed in a region between the pair of third portions 81 and a region between the pair of fourth portions 91 which have a relatively large influence on the moment of inertia of the first movable portion 3 around the X-axis, whereas the first extending portion 62 and the second extending portion 72 are formed in a region between the pair of first portions 61 and a region between the pair of second portions 71, respectively, which have a relatively small influence, so that reliability can be ensured through the reinforcement of the rib portion 50 while realizing good swinging of the first movable portion 3 through the suppression of an increase in the moment of inertia of the first movable portion 3 around the X-axis. In addition, a decrease in the resonance frequency of the first movable portion 3 around the X-axis can be suppressed by suppressing an increase in the moment of inertia of the first movable portion 3 around the X-axis. Therefore, according to the mirror device 1, distortion of the mirror surface 10 can be effectively suppressed, and reliability can be ensured while realizing good swinging of the first movable portion 3.

The first extending portion 62 is connected to the pair of first portions 61, and the second extending portion 72 is connected to the pair of second portions 71. Accordingly, distortion of the first movable portion 3 can be more effectively suppressed. In addition, the rigidity of the first rib portion 60 and the second rib portion 70 can be increased, and damage to the rib portion 50 or the peeling of the rib portion 50 can be suppressed.

The pair of first portions 61 are connected to each other at the central portion 51 (at the side of the reference position), and the pair of second portions 71 are connected to each other at the central portion 51. Accordingly, the rigidity of the first rib portion 60 and the second rib portion 70 can be increased, and damage to the rib portion 50 or the peeling of the rib portion 50 can be suppressed.

The pair of third portions 81 are connected to each other at the central portion 51, and the pair of fourth portions 91 are connected to each other at the central portion 51. Accordingly, the rigidity of the third rib portion 80 and the fourth rib portion 90 can be increased, and damage to the rib portion 50 or the peeling of the rib portion 50 can be suppressed.

The rib portion 50 includes the central portion 51 (reference portion) disposed at the reference position in a plan view, and the pair of first portions 61, the pair of second portions 71, the pair of third portions 81, and the pair of fourth portions 91 are connected at the central portion 51. Accordingly, the rigidity of the rib portion 50 can be increased, and damage to the rib portion 50 or the peeling of the rib portion 50 can be suppressed.

In a plan view, the first extending portion 62 is curved to be convex toward the one side in the direction D1, and the second extending portion 72 is curved to be convex toward the other side in the direction D1. Accordingly, distortion of the body portion 31 can be more effectively suppressed. Particularly, dynamic distortion and static distortion that occur remarkably at the outer edge portion of the body portion 31 can be effectively suppressed.

Distortion that occurs in the body portion 31 includes dynamic distortion and static distortion. The dynamic distortion is distortion that occurs when the first torsion bars 5 are torsionally deformed to cause the first movable portion 3 to swing. The dynamic distortion also occurs because stress generated in the first torsion bars 5 when the first torsion bars 5 are torsionally deformed is transmitted to the body portion 31 via the ring-shaped portion 32. The static distortion is distortion that occurs due to the formation of the mirror surface 10 and the protection film. The static distortion also occurs due to a difference in thermal expansion coefficient between different materials (for example, silicon that is the material of the SOI substrate 100, SiN that is the material of the insulating layer, a metal material constituting the coils 14 and 15, and the like). Both the dynamic distortion and the static distortion are particularly likely to occur at the outer edge portion of the body portion 31. Specifically, the dynamic distortion is likely to occur in the vicinities of the connection locations between the first movable portion 3 and the first torsion bars 5 where stress occurs during swinging of the first movable portion 3, or at a position away from the X-axis (swing axis) which is strongly affected by the moment of inertia. The static distortion is likely to occur at the outer edge portion of the body portion 31 due to the influence of a metal film or an inorganic material film laminated on the body portion 31. In addition, the static distortion is also likely to occur in the vicinities of the connection locations between the first movable portion 3 and the first torsion bars 5. The reason is that distortion occurring in the second movable portion 4 due to the formation of the coils 14 and 15 (or a piezoelectric element in the case of piezoelectric drive) can be transmitted to the first movable portion 3 via the first torsion bars 5. When distortion occurs in the body portion 31 (mirror surface 10), an adverse influence such as the distortion of a laser rib with which the mirror surface 10 is irradiated can occur. In this regard, in the mirror device 1, as described above, the first extending portion 62 and the second extending portion 72 are provided, so that rigidity at the outer edge portion of the body portion 31 can be increased, and distortion (dynamic distortion and static distortion) of the body portion 31 can be suppressed.

The first extending portion 62 is connected to the end portions 61b on the opposite side of the pair of first portions 61 from the central portion 51 (reference position), and the second extending portion 72 is connected to the end portions 71b on the opposite side of the pair of second portions 71 from the central portion 51. Accordingly, distortion of the first movable portion 3 can be more effectively suppressed. In addition, since the first extending portion 62 and the second extending portion 72 are formed in regions close to the outer edge 31c of the body portion 31, distortion of the first movable portion 3 can be more effectively suppressed.

Each of the pair of first portions 61, the pair of second portions 71, the pair of third portions 81, and the pair of fourth portions 91 extends straight, and in a plan view, each of the angle θ1 between the pair of first portions 61 and the angle θ2 between the pair of second portions 71 is larger than each of the angle θ3 between the pair of third portions 81 and the angle θ4 between the pair of fourth portions 91. Accordingly, since the region between the first portions 61 and the region between the second portions 71 become wider, the first extending portion 62 and the second extending portion 72 can be lengthened, and as a result, distortion of the body portion 31 can be more effectively suppressed.

The following relationships can be satisfied.

$$\begin{matrix}θ3 < θ 1 < 3 \times θ 3 \\ θ4 < θ1 < 3 \times θ 4 \\ θ3 < θ2 < 3 \times θ 3 \\ θ4 < θ2 < 3 \times θ 4\end{matrix}$$

Accordingly, since the length of the first extending portion 62 and the second extending portion 72 can be made less than or equal to a predetermined length, distortion of the body portion 31 can be suppressed while suppressing an increase in the moment of inertia of the first movable portion 3 around the X-axis.

Each of the length L61 of the first portions 61 and the length L71 of the second portions 71 is longer than each of the length L81 of the third portions 81 and the length L91 of the fourth portions 91. Accordingly, an increase in the moment of inertia of the first movable portion 3 around the X-axis can be further suppressed.

The reference position coincides with the center P of the first movable portion 3 in a plan view. Accordingly, the rib portion 50 can be disposed on the first movable portion 3 in a well-balanced manner, and distortion of the first movable portion 3 can be effectively suppressed. In a plan view, the inner edge 62a of the first extending portion 62 is smoothly connected to the inner edges 61a of the pair of first portions 61, and the inner edge 72a of the second extending portion 72 is smoothly connected to the inner edges 71a of the pair of second portions 71. The closer a portion on the first movable portion 3 is to the outer edge portion, the more likely distortion is to occur at the portion; however, with such a configuration, stress can be dispersed, and damage to the first rib portion 60 and the second rib portion 70 or the peeling of the first rib portion 60 and the second rib portion 70 can be suppressed.

In a plan view, the inner edges 81a of the pair of third portions 81 are smoothly connected to each other, and the inner edges 91a of the pair of fourth portions 91 are smoothly connected to each other. Since the rib portion 50 is not formed in the region between the third portions 81 and the region between the fourth portions 91, the third rib portion 80 and the fourth rib portion 90 are likely to become structurally weak, particularly, stress is likely to concentrate on the connection location between the pair of third portions 81 and the connection location between the pair of fourth portions 91; however, with such a configuration, stress can be dispersed, and damage to the third rib portion 80 and the fourth rib portion 90 or the peeling of the third rib portion 80 and the fourth rib portion 90 can be suppressed.

The first movable portion 3 includes the body portion 31 including the first surface 31a and the second surface 31b; the ring-shaped portion 32 surrounding the body portion 31 with the gap G interposed therebetween in a plan view, and connected to the first torsion bars 5; and the first connection portion 33 and the second connection portion 34 that connect the ring-shaped portion 32 to the body portion 31. The mirror surface 10 is formed on the first surface 31a, and the rib portion 50 is formed on the second surface 31b. Accordingly, the first movable portion 3 is connected to the first torsion bars 5 via the ring-shaped portion 32, so that the occurrence that stress generated in the first torsion bars 5 during swinging of the first movable portion 3 is transmitted to the first movable portion 3 can be suppressed, and dynamic distortion of the first movable portion 3 can be suppressed. In addition, the transmission of the stress to the rib portion 50 can be suppressed, and damage to the rib portion 50 or the peeling of the rib portion 50 can be suppressed.

The first connection portion 33 is disposed on the one side in the direction D2 with respect to the body portion 31, and the second connection portion 34 is disposed on the other side in the direction D2 with respect to the body portion 31. The first connection portion 33 includes the pair of first connection regions 33a separated from each other by the space S1, and each of the first connection regions 33a is connected to the body portion 31 and the ring-shaped portion 32. The second connection portion 34 includes the pair of second connection regions 34a separated from each other by the space S2, and each of the second connection regions 34a is connected to the body portion 31 and the ring-shaped portion 32. The pair of third portions 81 extend toward the pair of respective first connection regions 33a, and the pair of fourth portions 91 extend toward the pair of respective second connection regions 34a. Accordingly, the first connection portion 33 includes the pair of first connection regions 33a and the second connection portion 34 includes the pair of second connection regions 34a, so that the occurrence that stress generated in the first torsion bars 5 during swinging of the first movable portion 3 is transmitted to the first movable portion 3 and the rib portion 50 can be further suppressed. Namely, stress can be effectively relieved by intentionally forming portions with a small width and low rigidity such as the first connection regions 33a and the second connection regions 34a. In addition, rigidity is likely to be low in the vicinities of the first connection regions 33a and the second connection regions 34a; however, since the pair of third portions 81 extend toward the pair of respective first connection regions 33a and the pair of fourth portions 91 extend toward the pair of respective second connection regions 34a, rigidity in the vicinities of the first connection regions 33a and the second connection regions 34a can be increased.

In a plan view, the third portions 81 do not reach the first connection regions 33a, and fourth portions 91 do not reach the second connection regions 34a. Since relatively large dynamic distortion occurs in the ring-shaped portion 32 or the first connection regions 33a and the second connection regions 34a, with such a configuration, damage to the third rib portion 80 and the fourth rib portion 90 or the peeling of the third rib portion 80 and the fourth rib portion 90 can be suppressed.

The distance T3 between the third portions 81 and the first connection regions 33a is smaller than the maximum width W33a of the first connection regions 33a, and the distance T4 between the fourth portions 91 and the second connection regions 34a is smaller than the maximum width W34a of the second connection regions 34a. Accordingly, rigidity in the vicinities of the first connection regions 33a and the second connection regions 34a can be increased.

### Modification Examples

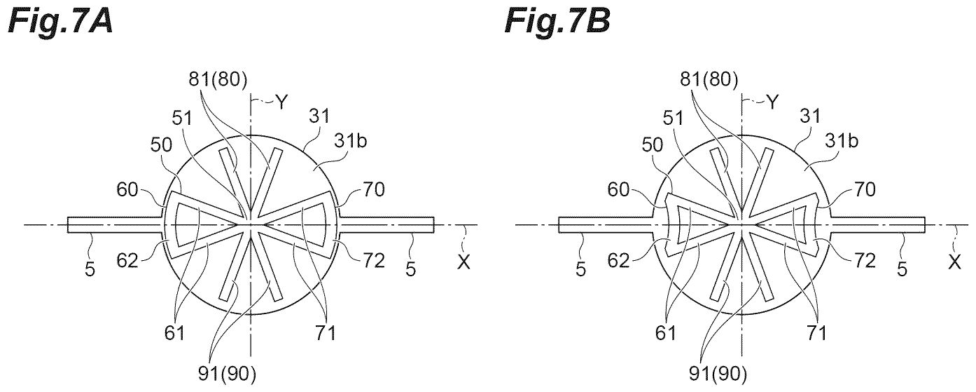

As in a first modification example shown in FIG. 7A, the first movable portion 3 may include only the body portion 31 without including the ring-shaped portion 32, the first connection portion 33, and the second connection portion 34. In the first modification example, the first torsion bars 5 are directly connected to the body portion 31. The first extending portion 62 and the second extending portion 72 do not include the protrusion portions 63 and 73, and the entirety of the rib portion 50 overlaps the body portion 31 in a plan view. According to a second modification example shown in FIG. 7B, in the first modification example, the first extending portion 62 and the second extending portion 72 are curved in an arc shape to be convex toward a central portion 51 side in the direction D1 in a plan view.

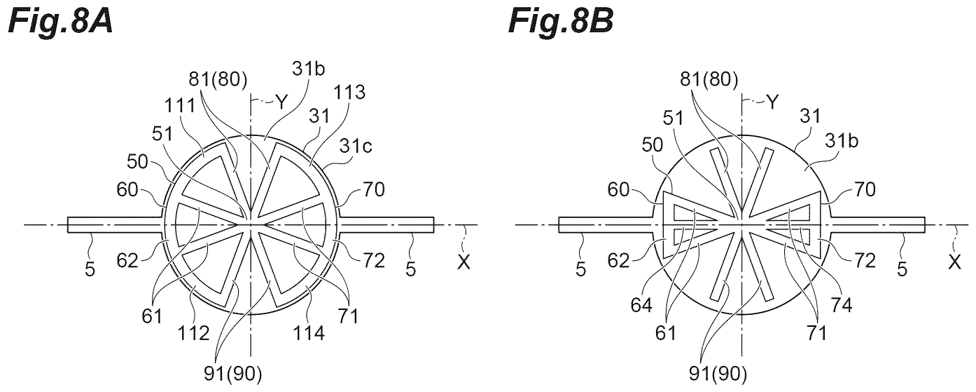

According to a third modification example shown in FIG. 8A, in the first modification example, the rib portion 50 further includes a portion 111 connected to one first portion 61 of the first rib portion 60 and one third portion 81 of the third rib portion 80; a portion 112 connected to the other first portion 61 of the first rib portion 60 and one fourth portion 91 of the fourth rib portion 90; a portion 113 connected to one second portion 71 of the second rib portion 70 and the other third portion 81 of the third rib portion 80; and a portion 114 connected to the other second portion 71 of the second rib portion 70 and the other fourth portion 91 of the fourth rib portion 90. The portions 111 to 114 extend along the outer edge 31c of the body portion 31.

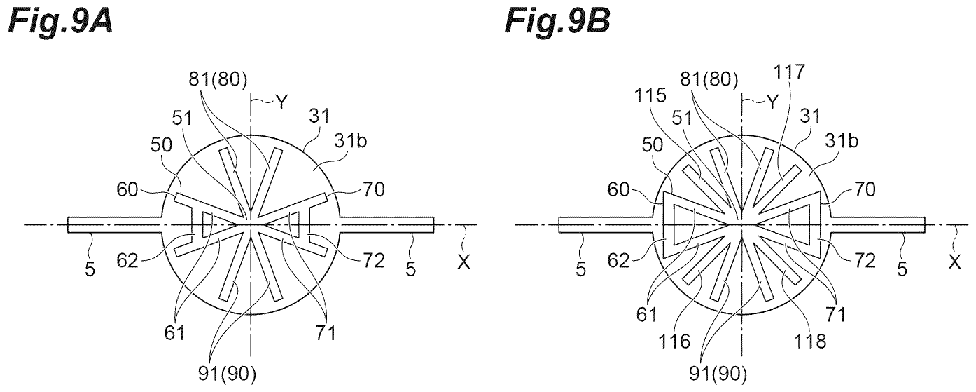

According to a fourth modification example shown in FIG. 8B, in the first modification example, the first extending portion 62 and the second extending portion 72 extend parallel to the direction D2. In addition, the first rib portion 60 further includes a portion 64 extending from the central portion 51 to reach the first extending portion 62 on the X-axis, and the second rib portion 70 further includes a portion 74 extending from the central portion 51 to reach the second extending portion 72 on the X-axis. According to a fifth modification example shown in FIG. 9A, in the first modification example, the first extending portion 62 extends parallel to the direction D2, and is connected to intermediate portions of the pair of first portions 61. In addition, the second extending portion 72 extends parallel to the direction D2, and is connected to intermediate portions of the pair of second portions 71. According to a sixth modification example shown in FIG. 9B, in the fourth modification example, in a plan view, the rib portion 50 further includes a portion 115 extending between the first rib portion 60 and the third rib portion 80; a portion 116 extending between the first rib portion 60 and the fourth rib portion 90; a portion 117 extending between the second rib portion 70 and the third rib portion 80; and a portion 118 extending between the second rib portion 70 and the fourth rib portion 90. The portions 115 to 118 extend straight along directions inclined with respect to the direction D1 and the direction D2 in a plan view. Unlike the fourth modification example, the rib portion 50 of the sixth modification example does not include the portions 64 and 74.

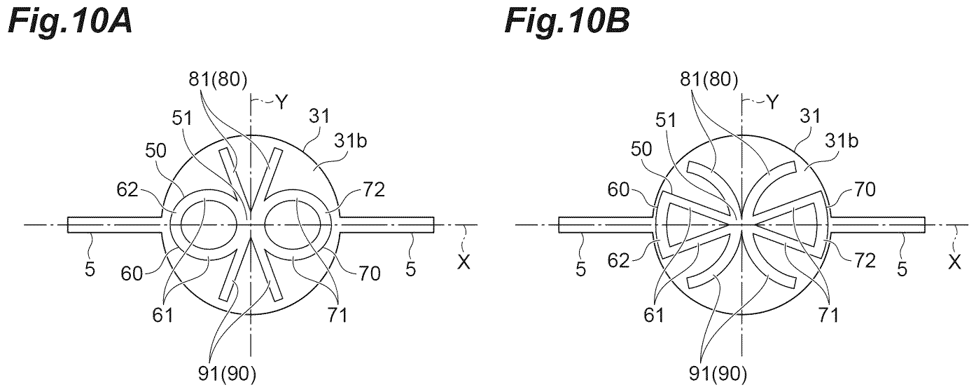

According to a seventh modification example shown in FIG. 10A, in the first modification example, the first rib portion 60 and the second rib portion 70 are formed in a circular shape in a plan view. In this case as well, the first rib portion 60 can be deemed to include the pair of first portions 61 and the first extending portion 62 extending therebetween, and the second rib portion 70 can be deemed to include the pair of second portions 71 and the second extending portion 72 extending therebetween. In such a manner, the first portions 61 and the second portions 71 may extend curvedly. In the example of FIG. 10A, the first portions 61 and the second portions 71 are curved in an arc shape to be convex toward the one side or the other side in the direction D2 in a plan view. According to an eighth modification example shown in FIG. 10B, in the first modification example, the pair of third portions 81 of the third rib portion 80 extend curvedly in an arc shape to be further separated from each other as the pair of third portions 81 extend away from the central portion 51 in a plan view. In addition, the pair of fourth portions 91 of the fourth rib portion 90 extend curvedly in an arc shape to be further separated from each other as the pair of fourth portions 91 extend away from the central portion 51 in a plan view.

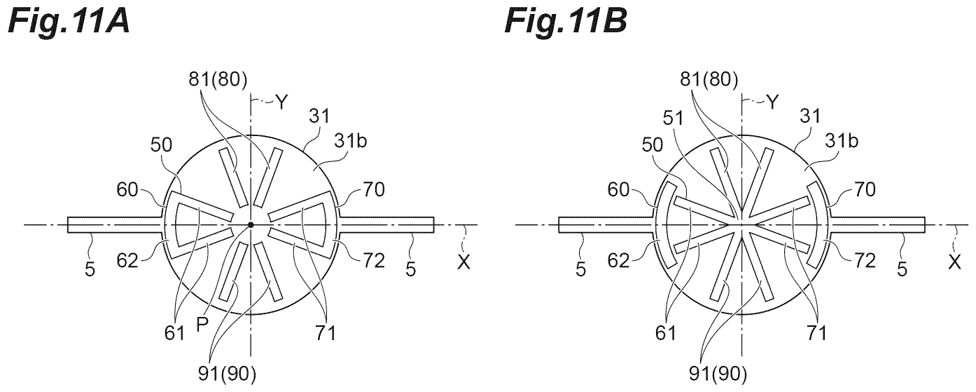

According to a ninth modification example shown in FIG. 11A, in the first modification example, the rib portion 50 does not include the central portion 51. In the ninth modification example, the pair of first portions 61 are not connected to each other on the side of the center P (the side of the reference position) (separated from each other). Similarly, the pair of second portions 71 are not connected to each other, the pair of third portions 81 are not connected to each other, and the pair of fourth portions 91 are not connected to each other on the side of the center P. In such a manner, the first portions 61 and the second portions 71 may extend from the side of the reference position toward the one side or the other side in the direction D1, and the third portions 81 and the fourth portions 91 may extend from the side of the reference position toward the one side or the other side in the direction D2.

According to a tenth modification example shown in FIG. 11B, in the first modification example, the first portions 61 are not connected to the first extending portion 62, and there is a gap between the first portions 61 and the first extending portion 62. In addition, the second portions 71 are not connected to the second extending portion 72, and there is a gap between the second portions 71 and the second extending portion 72. In the tenth modification example as well, the first extending portion 62 extends between the pair of first portions 61. In the tenth modification example, the first extending portion 62 extends in a region between line segments obtained by extending the pair of first portions 61 toward the side opposite to the central portion 51 along the respective extending directions. More specifically, an intermediate portion of the first extending portion 62 is disposed in this region. In such a manner, the fact that “the first extending portion extends between the pair of first portions” includes not only the case where “the first extending portion extends in the region between the pair of first portions” as in the above-described embodiment, but also the case where “the first extending portion extends in the region between the line segments obtained by extending the pair of first portions toward the side opposite to the reference position along the respective extending directions” as in the tenth modification example. This point also applies to the second extending portion and the second portions of the second rib portion. Namely, in the tenth modification example as well, the second extending portion 72 extends between the pair of second portions 71. In addition, the fact that “the rib portion does not include a portion formed between the pair of third portions” means not only that “the rib portion does not include a portion formed in the region between the pair of third portions”, but also that “the rib portion does not include a portion formed in a region between line segments obtained by extending the pair of third portions toward the side opposite to the reference position along the respective extending directions”. This point also applies to the fourth portions of the fourth rib portion. Incidentally, in the ninth modification example as well, the pair of first portions 61 and the first extending portion 62 can be deemed to form a region (region with no rib) where the rib portion 50 is not formed thereinside. In the tenth modification example as well, the pair of second portions 71 and the second extending portion 72 can be deemed to form a region (region with no rib) where the rib portion 50 is not formed thereinside.

In the first to tenth modification examples as well described above, similarly to the above-described embodiment, distortion of the mirror surface 10 can be effectively suppressed, and reliability can be ensured while realizing good swinging of the first movable portion 3.

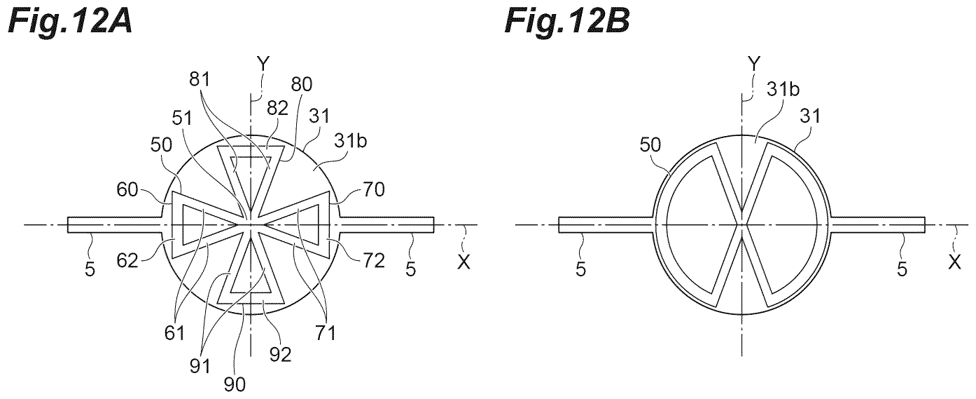

In a first comparative example shown in FIG. 12A, unlike the mirror device 1 of the embodiment, the rib portion 50 includes a portion 82 formed between the pair of third portions 81, and a portion 92 formed between the pair of fourth portions 91. The portions 82 and 92 extend to intersect the Y-axis (in this example, to be orthogonal). In a second comparative example shown in FIG. 12B, the rib portion 50 does not include the pair of first portions 61, the first extending portion 62, the pair of second portions 71, the second extending portion 72, the pair of third portions 81, and the pair of fourth portions 91 as in the mirror device 1 of the embodiment. The rib portion 50 of the second comparative example can be deemed to have a configuration in which in the rib portion 50 of the embodiment, one first portion 61 is integrally formed with one third portion 81 (configured as one portion) (shared with each other), the other first portion 61 is integrally formed with one fourth portion 91, one second portion 71 is integrally formed with the other third portion 81, and the other second portion 71 is integrally formed with the other fourth portion 91. Namely, the rib portion 50 of the second comparative example does not include the pair of first portions 61, the pair of second portions 71, the pair of third portions 81, and the pair of fourth portions 91 configured as portions different from one another.

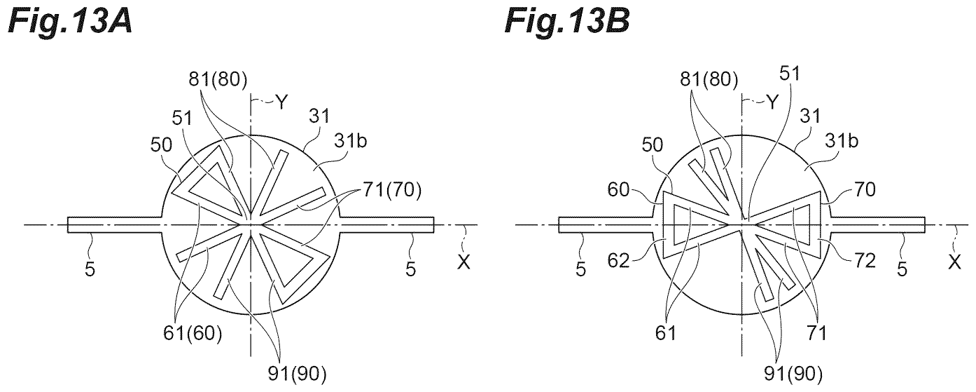

In a third comparative example shown in FIG. 13A, the rib portion 50 does not include a portion extending between the pair of first portions 61 of the first rib portion 60 (namely, a portion extending to intersect the X-axis between the pair of first portions 61), and a portion extending between the pair of second portions 71 of the second rib portion 70 (namely, a portion extending to intersect the X-axis between the pair of second portions 71). In a fourth comparative example shown in FIG. 13B, the pair of third portions 81 of the third rib portion 80 do not face each other with the Y-axis interposed therebetween, and the pair of fourth portions 91 of the fourth rib portion 90 do not face each other with the Y-axis interposed therebetween.

The present disclosure is not limited to the above-described embodiment and modification examples. In the above-described embodiment, the rib portion 50 is not formed at all between the pair of third portions 81; however, the rib portion 50 may only not include a portion formed between the pair of third portions 81 and extending to intersect the Y-axis in a plan view, for example, a portion extending not to intersect the Y-axis in a plan view (portion extending while being away from the Y-axis) may be formed between the pair of third portions 81. In such a case as well, similarly to the above-described embodiment, reliability can be ensured by reinforcing the rib portion 50 while realizing good swinging of the first movable portion 3 by suppressing an increase in the moment of inertia of the first movable portion 3 around the X-axis. However, as in the above-described embodiment, when the rib portion 50 is not formed at all between the pair of third portions 81, an increase in the moment of inertia of the first movable portion 3 around the X-axis can be further suppressed. Similarly, in the above-described embodiment, the rib portion 50 is not formed at all between the pair of fourth portions 91; however, the rib portion 50 may only not include a portion formed between the pair of fourth portions 91 and extending to intersect the Y-axis in a plan view, for example, a portion extending not to intersect the Y-axis in a plan view (portion extending while being away from the Y-axis) may be formed between the pair of fourth portions 91.

The material and shape of each configuration are not limited to the material and shape described above, and various materials and shapes can be adopted. For example, the body portion 31, the ring-shaped portion 32, and the mirror surface 10 may be formed in any shape such as a circular shape, an elliptical shape, a quadrangular shape, or a rhombus shape. The shape of the second movable portion 4 is not limited to the above-described shape.

The first extending portion 62 may only extend between the pair of first portions 61, and may not be connected to the pair of first portions 61. The second extending portion 72 may only extend between the pair of second portions 71, and may not be connected to the pair of second portions 71.

Each of the angle θ1 between the pair of first portions 61 and the angle θ2 between the pair of second portions 71 may be equal to or smaller than the angle θ3 between the pair of third portions 81 and the angle θ4 between the pair of fourth portions 91. Each of the angles θ1 and θ2 may be larger than three times the angles θ3 and θ4. Each of the length L61 of the first portions 61 and the length L71 of the second portions 71 may be equal to or shorter than the length L81 of the third portions 81 and the length L91 of the fourth portions 91.

The reference position where the central portion 51 is disposed may be set at any position, and may not necessarily coincide with the center P of the body portion 31 in a plan view. In a plan view, the inner edge 62a of the first extending portion 62 may not be smoothly connected to the inner edges 61a of the pair of first portions 61, and the inner edge 72a of the second extending portion 72 may not be smoothly connected to the inner edges 71a of the pair of second portions 71. In a plan view, the inner edges 81a of the pair of third portions 81 may not be smoothly connected, and the inner edges 91a of the pair of fourth portions 91 may not be smoothly connected.

The first connection portion 33 may not include the pair of first connection regions 33a separated from each other by the space S1, and may be made up of one region that is not separated by a space. Similarly, the second connection portion 34 may not include the pair of second connection regions 34a separated from each other by the space S2, and may be made up of one region that is not separated by a space. The pair of third portions 81 may not extend toward the pair of first connection regions 33a, and the pair of fourth portions 91 may not extend toward the pair of second connection regions 34a. The body portion 31 may only be formed from at least the first semiconductor layer 101, and the rib portion 50 may only be formed from at least the second semiconductor layer 102. For example, the body portion 31 may be formed from the first semiconductor layer 101 and the insulating layer 103, and the rib portion 50 may be formed from the second semiconductor layer 102.

The drive elements of the first movable portion 3 and the second movable portion 4 are not limited to the coils 14 and 15, and may be, for example, piezoelectric elements. The coil 15 may be provided in the first movable portion 3 (for example, the ring-shaped portion 32). The motion of the first movable portion 3 may be linear motion (non-resonance motion). The second movable portion 4 and the second torsion bars 6 may be omitted. In this case, the first movable portion 3 may be directly coupled to the support portion 2 by the first torsion bars 5. In this case, the motion of the first movable portion 3 may be resonance motion or linear motion. Namely, in the above-described embodiment, the mirror device 1 includes a resonance axis and a linear axis; however, the mirror device 1 may include only one of the resonance axis and the linear axis. The first axis around which the first movable portion 3 swings and the second axis around which the second movable portion 4 swings may intersect each other at an angle other than being perpendicular, may be parallel to each other, or may be located on the same straight line. The mirror surface 10 may be configured as a diffraction grating that diffracts or reflects light. In this case, the mirror surface 10 may be formed, for example, by a metal film formed along a predetermined diffraction grating pattern. Alternatively, the mirror surface 10 may be formed by etching silicon (first semiconductor layer 101) (may be formed of a surface of the first semiconductor layer 101).

What is claimed is:

1. A mirror device comprising:
a support portion;
a movable portion having a first surface and a second surface opposite to the first surface, a mirror surface being formed on the first surface and a rib portion being formed on the second surface; and
a coupling portion that couples the movable portion to the support portion such that the movable portion is swingable around a first axis,
wherein the rib portion includes a first rib portion, a second rib portion, a third rib portion, and a fourth rib portion,
when a direction parallel to the first axis is a first direction, an axis perpendicular to both the first direction and a third direction passing through a center of the movable portion when viewed in the third direction perpendicular to the second surface is a second axis, and a direction parallel to the second axis is a second direction, the first rib portion includes a pair of first portions extending from a side of a reference position toward one side in the first direction and facing each other with the first axis interposed between the pair of first portions in the second direction, and a first extending portion extending between the pair of first portions to intersect the first axis when viewed in the third direction, the second rib portion includes a pair of second portions extending from the side of the reference position toward the other side in the first direction and facing each other with the first axis interposed between the pair of second portions in the second direction, and a second extending portion extending between the pair of second portions to intersect the first axis when viewed in the third direction, the third rib portion includes a pair of third portions extending from the side of the reference position toward one side in the second direction and facing each other with the second axis interposed between the pair of third portions in the first direction, and the fourth rib portion includes a pair of fourth portions extending from the side of the reference position toward the other side in the second direction and facing each other with the second axis interposed between the pair of fourth portions in the first direction,
the rib portion does not include a portion formed between the pair of third portions and extending to intersect the second axis when viewed in the third direction, and a portion formed between the pair of fourth portions and extending to intersect the second axis when viewed in the third direction, and
the pair of first portions, the pair of second portions, the pair of third portions, and the pair of fourth portions are portions different from one another.

2. The mirror device according to claim 1,
wherein the first extending portion is connected to the pair of first portions, and the second extending portion is connected to the pair of second portions.

3. The mirror device according to claim 1,
wherein the pair of first portions are connected to each other on the side of the reference position, and the pair of second portions are connected to each other on the side of the reference position.

4. The mirror device according to claim 1,
wherein the pair of third portions are connected to each other on the side of the reference position, and the pair of fourth portions are connected to each other on the side of the reference position.

5. The mirror device according to claim 1,
wherein the rib portion includes a reference portion disposed at the reference position when viewed in the third direction, and
the pair of first portions, the pair of second portions, the pair of third portions, and the pair of fourth portions are connected to the reference portion.

6. The mirror device according to claim 1,
wherein when viewed in the third direction, the first extending portion is curved to be convex toward the one side in the first direction, and the second extending portion is curved to be convex toward the other side in the first direction.

7. The mirror device according to claim 1,
wherein the first extending portion is connected to end portions on an opposite side of the pair of first portions from the reference position, and the second extending portion is connected to end portions on an opposite side of the pair of second portions from the reference position.

8. The mirror device according to claim 1,
wherein each of the pair of first portions, the pair of second portions, the pair of third portions, and the pair of fourth portions extends straight, and
when viewed in the direction perpendicular to the second surface, if an angle between the pair of first portions is θ1, an angle between the pair of second portions is θ2, an angle between the pair of third portions is θ3, and an angle between the pair of fourth portions is θ4, each of θ1 and θ2 is larger than each of θ3 and θ4.

9. The mirror device according to claim 8,
wherein the following relationships are satisfied.
$$\begin{matrix}θ3 < θ 1 < 3 \times θ 3 \\ θ4 < θ1 < 3 \times θ 4 \\ θ3 < θ2 < 3 \times θ 3 \\ θ4 < θ2 < 3 \times θ 4\end{matrix}$$

10. The mirror device according to claim 1,
wherein each of a length of the pair of first portions and a length of the pair of second portions is longer than each of a length of the pair of third portions and a length of the pair of fourth portions.

11. The mirror device according to claim 1,
wherein the reference position coincides with the center of the movable portion when viewed in the third direction.

12. The mirror device according to claim 2,
wherein when viewed in the third direction, an inner edge of the first extending portion is smoothly connected to inner edges of the pair of first portions, and an inner edge of the second extending portion is smoothly connected to inner edges of the pair of second portions.

13. The mirror device according to claim 4,
wherein when viewed in the third direction, inner edges of the pair of third portions are smoothly connected to each other, and inner edges of the pair of fourth portions are smoothly connected to each other.

14. The mirror device according to claim 1,
wherein the movable portion includes a body portion including the first surface and the second surface, a ring-shaped portion surrounding the body portion with a gap interposed between the ring-shaped portion and the body portion when viewed in the third direction, and connected to the coupling portion, and a connection portion that connects the ring-shaped portion to the body portion, and
the mirror surface is formed on the first surface of the body portion, and the rib portion is formed on the second surface of the body portion.

15. The mirror device according to claim 14,
wherein the movable portion includes a first connection portion and a second connection portion as the connection portion, the first connection portion is disposed on the one side in the second direction with respect to the body portion, and the second connection portion is disposed on the other side in the second direction with respect to the body portion,
the first connection portion includes a pair of first connection regions separated from each other by a space, each of the pair of first connection regions is connected to the body portion and the ring-shaped portion, the second connection portion includes a pair of second connection regions separated from each other by a space, and each of the pair of second connection regions is connected to the body portion and the ring-shaped portion, and
the pair of third portions extend toward the pair of respective first connection regions, and the pair of fourth portions extend toward the pair of respective second connection regions.

16. The mirror device according to claim 15,
wherein when viewed in the third direction, the pair of third portions do not reach the pair of first connection regions, and the pair of fourth portions do not reach the pair of second connection regions.

17. The mirror device according to claim 16,
wherein a distance between the pair of third portions and the pair of first connection regions is smaller than a maximum width of each of the pair of first connection regions, and a distance between the pair of fourth portions and the pair of second connection regions is smaller than a maximum width of each of the pair of second connection regions.
